(19) United States
(12) Patent Application Publication
(10) Pub. No.: US 2023/0085028 A1
(43) Pub. Date: Mar. 16, 2023

(54) METHOD OF DETECTING ABNORMALITY

(71) Applicant: Samsung Electronics Co., Ltd., Suwon-si (KR)

(72) Inventors: Jiho GHIL, Yongin-si (KR); Taeyoung ROH, Suwon-si (KR); Taehwa OH, Suwon-si (KR); Bumsuk CHUNG, Hwaseong-si (KR); Bokyoung KANG, Hwaseong-si (KR)

(73) Assignee: Samsung Electronics Co., Ltd., Suwon-si (KR)

(21) Appl. No.: 17/739,528

(22) Filed: May 9, 2022

(30) Foreign Application Priority Data
Sep. 14, 2021 (KR) 10-2021-0122546

(51) Int. Cl. G06F 11/07; G06Q 50/04

(52) U.S. Cl. CPC G06F 11/076; G06Q 50/04; G06F 11/0736

(57) ABSTRACT

A method of detecting abnormalities includes: calculating a reference failure rate using failure data at a plurality of points in time included in a particular period; calculating a detection failure rate and weighting, corresponding to failure data at a detection time point after the particular period, using the reference failure rate; calculating an abnormality index based on multiplying the detection failure rate by the weighting; comparing the abnormality index with an index corresponding to a control limit for stably controlling a failure rate; and detecting whether the failure data at the detection time point is abnormal, based on a result of the comparison of the abnormality index with the index corresponding to the control limit.

### CROSS-REFERENCE TO RELATED APPLICATION

This application claims benefit of priority to Korean Patent Application No. 10-2021-0122546 filed on Sep. 14, 2021 in the Korean Intellectual Property Office, the disclosure of which is incorporated herein by reference in its entirety.

### BACKGROUND

The present inventive concepts relate to methods of detecting abnormalities.

With recent advances in semiconductor processing technology, performance and reliability of products produced in the semiconductor industry are gradually improving. In particular, semiconductor products may be produced to have a low failure rate of several parts per million (PPM). Produced semiconductor products may be managed so as not to exceed a set target failure rate. However, a management system according to the related art has used a method of managing a failure rate in response to failure data, exceeding a target failure rate, after obtaining the failure data. A method of detecting abnormalities according to the related art is an intuitive method, but may have difficulty in making an optimal response at the optimal time because it does not take into account variability depending on a time point at which quality information is updated, the number of samples, and/or a changing trend of a failure rate.

### SUMMARY

Some example embodiments provide a method of detecting abnormalities, in which detection of abnormalities is performed based on a detection failure rate, calculated by an exact test method, and weighting, calculated based on a difference between failure data and target failure data, such that a failure rate is detected in advance in a field having a significantly low failure rate to effectively manage a risk.

According to some example embodiments, a method of detecting abnormalities includes: calculating a reference failure rate using failure data at a plurality of points in time included in a particular period; calculating a detection failure rate and weighting, corresponding to failure data at a detection time point after the particular period, using the reference failure rate; calculating an abnormality index based on multiplying the detection failure rate by the weighting; comparing the abnormality index with an index corresponding to a control limit for stably controlling a failure rate; and detecting whether the failure data at the detection time point is abnormal, based on a result of the comparison.

According to some example embodiments, a method of detecting abnormalities includes: calculating a reference failure rate using failure data at a plurality of points in time included in a particular period; calculating a detection failure rate according to an exact test using the reference failure rate and failure data at a detection time point after the particular period; calculating an abnormality index using the detection failure rate; and detecting whether the failure data at the detection time point is abnormal, based on the abnormality index.

According to some example embodiments, a method of detecting abnormalities includes: calculating a reference failure rate using failure data at a plurality of points in time included in a particular period; calculating a standard deviation of the failure data at the plurality of points in time, included in the particular period, using the reference failure rate; defining a plurality of state areas including a first area, a second area, and a third area divided based on the standard deviation, a boundary between the second area and the third area corresponding to a size of target failure data; determining an area, corresponding to a state of failure data at a detection time point after the particular period, among the plurality of state areas; and calculating weighting based on a difference between the failure data at the detection time point and the target failure data.

### BRIEF DESCRIPTION OF DRAWINGS

The above and other aspects, features, and advantages of the present inventive concepts will be more clearly understood from the following detailed description, taken in conjunction with the accompanying drawings.

FIG. 1 is a diagram illustrating an issue which may occur in a method of detecting abnormalities according to some example embodiments.

FIG. 2 is a flowchart illustrating a method of detecting abnormalities according to some example embodiments.

FIG. 3 is a flowchart illustrating a method of detecting abnormalities according to some example embodiments.

FIGS. 4, 5, and 6 are diagram illustrating an effect of a method of detecting abnormalities according to some example embodiments.

FIG. 7 is a flowchart illustrating a method of detecting abnormalities according to some example embodiments.

FIG. 8 is a diagram illustrating a plurality of state areas defined in a method of detecting abnormalities according to some example embodiments.

FIGS. 9 and 10 are diagrams illustrating an effect of a method of detecting abnormalities according to some example embodiments.

FIG. 11 is a flowchart illustrating a method of detecting abnormalities according to some example embodiments.

FIG. 12 is a diagram illustrating an application example of a method of detecting abnormalities some example embodiments.

FIGS. 13A, 13B, and 13C are diagrams illustrating an application example of a method of detecting abnormalities some example embodiments.

FIG. 14 is a block diagram of an electronic device according to some example embodiments.

### DETAILED DESCRIPTION

Hereinafter, example embodiments will be described with reference to the accompanying drawings.

As described herein, when an operation is described to be performed “by” performing additional operations, it will be understood that the operation may be performed “based on” the additional operations, which may include performing said additional operations alone or in combination with other further additional operations.

In the descriptions below, terms “upper,” “upper portion,” “upper surface,” “lower,” “lower portion,” “lower surface,” “side surface,” and the like, are used with reference to the diagrams unless otherwise indicated.

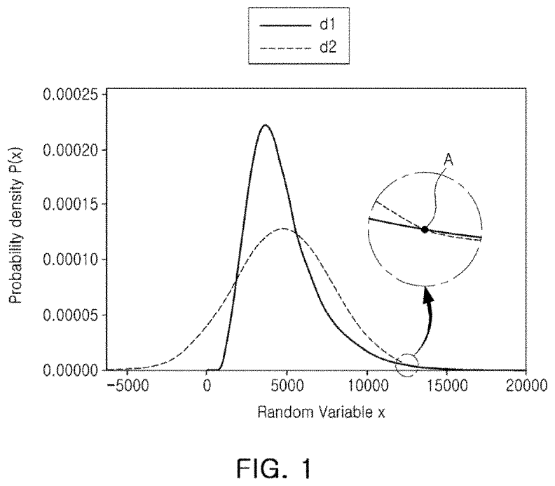

FIG. 1 is a diagram illustrating an issue which may occur in a method of detecting abnormalities according to some example embodiments.

A method of detecting abnormalities according to some example embodiments may be applied to a field having a significantly low failure rate. As an example, in the field of semiconductor industry, semiconductor products may be produced to have a significantly low failure rate of several parts per million (PPM) level. A method of detecting abnormalities according to some example embodiments may be applied to a manufacturing process that is used to produce (“manufacture”) one or more semiconductor products (e.g., electronic devices, semiconductor devices, etc.). A method for detecting abnormalities, when applied to one or more semiconductor products, may be used to selectively maintain/adjust process parameters and/or aspects (also referred to herein as process variables) of some or all of the manufacturing process (e.g., via generating a command signal that is transmitted to one or more devices configured to implement some or all of the adjustments), including selectively passing/excluding one or more semiconductor products manufactured by the manufacturing process for further inclusion in a further manufacturing process to manufacture an electronic device including the semiconductor product, distribution of the one or more semiconductor products as completed final products for packaging and/or sale, or the like.

Referring to FIG. 1, failure data having a significantly low failure rate may appear in the form of a first distribution d1. As an example, the first distribution d1 may be a distribution including failure data greater than 0 and significantly biased to 0. The failure data may indicate failure of one or more devices under test (DoT), such as one or more semiconductor products manufactured by a manufacturing process, with regard to a test performed on the device(s). Such a test may include an observation of the device for visible defects, applying electrical signals to an interface (e.g., electrodes, communication interface, etc.) of the device and processing a response signal received from an interface (same or different) of the device in response to the applied electrical signals to determine whether the device passes or fails the test, or the like.

Since the first distribution d1 does not satisfy normality, it may be approximated and processed as a normal distribution such as a second distribution d2. However, since the normal distribution is a symmetric distribution, the second distribution d2 may include failure data less than 0 and probability density may be reversed at a right tail portion of the first distribution d1 and the second distribution d2, for example, portion “A.” In other words, a control limit, which may control failure rate estimated based on the second distribution d2, may be estimated to be lower than a limit of actually controllable failure rate.

A field, to which the anomaly detection method according to some example embodiments is applied, has a significantly low failure rate, so that an underestimation issue may become severe as asymmetry of the failure data is increased.

As an example, in the case in which the control limit of the failure rate is at a level of 90%, the controllable failure rate level in the first distribution d1, a failure data distribution, may be lower than the controllable failure rate level in the second distribution d2, an approximated normal distribution. Therefore, such a case may not be problematic.

However, when (e.g., in response to) the control limit of the failure rate is 99% or more, the controllable failure rate level in the first distribution d1 may be increased to be higher than the controllable failure rate level in the second distribution d2, so that the control limit may be estimated to be lower than the actually controllable failure rate level. As an example, when (e.g., in response to) the estimated control limit is lower than the actual controllable failure rate level, unnecessary failure rate control may be involved and reliability of the production system may be deteriorated.

The above-described underestimation caused a limitation in that after the failure data at a detection time point exceeded the target failure data, there was no choice but to respond to such an issue. Such management may include selectively discarding semiconductor products associated with the failure data (e.g., semiconductor products tested to generate the failure data), re-routing such semiconductor products for repair, adjusting one or more parameters and/or aspects of manufacturing processes to manufacture semiconductor products, or the like. For example, a failure rate of a produced product was managed in a manner of simply determining whether the failure data obtained at the detection time point exceeded the target failure data. Although such a management method is intuitive, it may not take into account variability depending on a time point at which quality information is updated, a sample size, uncertainty based on a level of failure, and/or a changing trend of failure data.

In the method of detecting abnormalities according to some example embodiments, before detected failure data exceeds target failure data, an abnormally rising trend of a failure rate may be detected to quantify and manage the possibility that the failure data will exceed the target failure data. Accordingly, the failure rate may be preemptively managed based on an objective statistical fact rather than subjective judgment of managers. As a result, for example in the field of manufacturing semiconductor products, the failure rate many be preemptively managed (based on generating a command signal to cause an adjustment of one or more parameters and/or aspects of a manufacturing process to manufacture semiconductor products) in response to detecting an abnormal failure rate, to reduce the quantity and/or likelihood of defective semiconductor products that may need to be discarded and/or repaired instead of being distributed as final products and/or incorporated into larger electronic devices under manufacture, or the like. As a result, based on performing a method of detecting abnormalities according to some example embodiments, the performance, efficiency, and/or cost-effectiveness of a manufacturing process (e.g., a process of manufacturing semiconductor products) may be improved, thereby reducing excess expenditures of time and/or resources to manufacture products. Additionally, the reliability of products manufactured according to a manufacturing process for which a method of detecting abnormalities according to any of the example embodiments may be performed may be improved based on preemptive management of the failure rate associated therewith, thus improving the overall reliability of products (e.g., semiconductor products) manufactured according to the process.

In addition, according to the method of detecting abnormalities according to some example embodiments, abnormal change in failure data may be detected with high accuracy even in a field having a significantly low failure rate, such as a field of semiconductor industry.

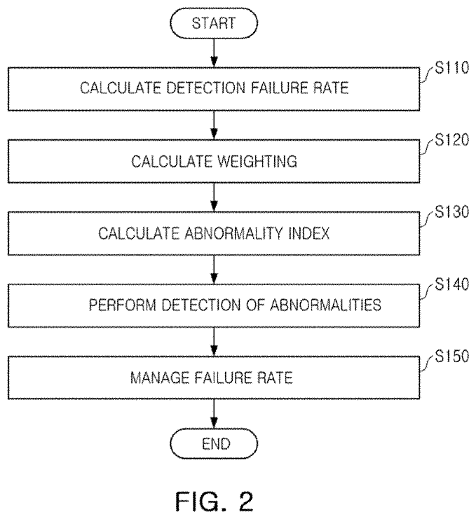

FIG. 2 is a flowchart illustrating a method of detecting abnormalities according to some example embodiments.

Referring to FIG. 2, a method of detecting abnormalities according to some example embodiments may include operation S110, in which a detection failure rate is calculated, and operation S120 in which weighting is calculated.

As an example, a detection failure rate may be calculated based on failure data at a detection time point and a plurality of pieces of failure data obtained during a particular (or, alternatively, predetermined) period before the detection time point. In the method of detecting abnormalities according to some example embodiments, a failure rate may be calculated using an exact test based on a binomial distribution to address an underestimation issue, which may occur when normal distribution approximation is used, and to improve detection accuracy.

Weighting may be calculated based on a difference between the failure data at a detection time point and particular (or, alternatively, predetermined) target failure data. As an example, when (e.g., in response to) the failure data at the detection time point is proximate to the target failure data, an increase in the detection failure rate is sensitively recognized. Meanwhile, when (e.g., in response to) the failure data at the detection time point is not proximate to the target failure data, an increase in the detection failure rate may be insensitively recognized.

In the case in which a failure rate is lower than the target failure rate when (e.g., in response to) the failure data is increased, the increased failure data may be within the target failure data. In addition, in the case in which the failure rate is proximate to the target failure rate even when (e.g., in response to) failure data having the same level is increased, the increased failure data may exceed the target failure data.

In the abnormality detection method according to some example embodiments, weighting may be applied to an abnormal increase in failure data to reduce probability that noise occurs due to an increase of the failure data when (e.g., in response to) a failure rate is lower than a target failure rate.

The method of detecting abnormalities according to some example embodiments may include operation S130 in which an abnormality index is obtained by multiplying the calculated detection failure rate by weighting. In operation S140, a determination may be made as to whether the detected failure data is abnormal, based on the obtained abnormality index. In operation S150, when (e.g., in response to) the abnormality index is detected to be outside of a controllable range, the failure data may be preemptively managed so that the abnormality index falls within the controllable range even before the failure data exceeds the target failure data.

In some example embodiments, for example in example embodiments where the failure data is representative of results of testing one or more devices (e.g., semiconductor products) manufactured according to a manufacturing process, the preemptive management of the failure data at S150 may include performing selective adjustments to one or more portions (e.g., parameters, aspects, etc.) of a manufacturing process associated with the failure data (e.g., adjusting actuators, fluid supply valves, programmed control of manufacturing devices, etc.) to preemptively reduce failures of tests by devices under test which are products of and/or representative of the manufacturing process. Such adjustments may be performed via manual adjustment of manufacturing devices and/or via adjusting programming of the control of the manufacturing devices by one or more electronic devices.

In some example embodiments, operation S150 may include generating and/or transmitting a command signal in response to a determination that the abnormality index is detected to be outside of a controllable range and/or that the failure data at the detection time point is abnormal. Such a command signal may be executed to cause performance of selective adjustments to one or more portions (e.g., parameters, aspects, etc.) of a manufacturing process associated with the failure data (e.g., adjusting actuators, fluid supply valves, programmed control of manufacturing devices, etc.) to preemptively reduce failures of tests by devices under test which are products of and/or representative of the manufacturing process. Such adjustments may be performed via manual adjustment of manufacturing devices and/or via adjusting programming of the control of the manufacturing devices by one or more electronic devices. Such a command signal may be executed by the same device performing the method shown in FIG. 2 and/or may be transmitted to an external device that is configured to perform some or all of the adjustments in response to the command signal. Such a command signal may be executed to cause a display device and/or user interface (e.g., a light emitting diode (LED), an LED screen, an organic light emitting diode (OLED) screen, etc.) to generate a warning notification to instruct an operator to perform adjustments to a manufacturing process, etc.

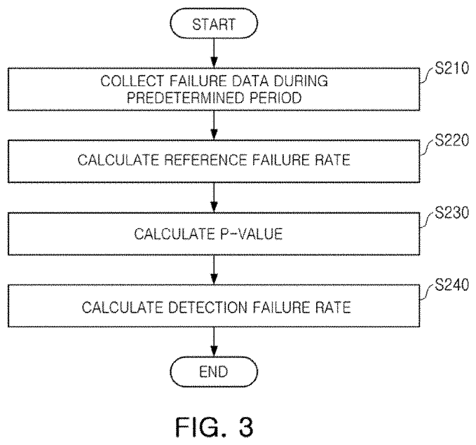

FIG. 3 is a flowchart illustrating a method of detecting abnormalities according to some example embodiments.

The flowchart illustrated in FIG. 3 may be a diagram illustrating a process of calculating a detection failure rate included in the method of detecting abnormalities according to the flowchart illustrated in FIG. 2.

Referring to FIG. 3, the method of detecting abnormalities according to some example embodiments may start with operation S210 in which failure data is collected at a plurality of points in time included in a particular (or, alternatively, predetermined) period. As an example, the particular (or, alternatively, predetermined) period may be a time period before a detection time point, and the plurality of points in time may be arranged at regular intervals. However, this is only an example and example embodiments may not be limited thereto. Failure data may be collected based on performing tests of one or more devices under test (e.g., semiconductor products that are manufactured according to a manufacturing process) over time, where the failure data may indicate occurrences of failures of the tests, timestamps and/or particular products associated with the tests, etc. Devices which “pass” the tests may be selectively included in further manufacturing of larger electronic devices and/or may be selectively distributed as final products. Devices which “fail” the tests may be selectively discarded or re-directed to be repaired and re-tested.

In operation S220, a reference failure rate, used to detect whether the failure data is abnormal at the detection time point, may be calculated using the collected failure data. As an example, a statistical hypothesis test may be used to detect whether the failure data is abnormal at the detection time point.

In operation S230, when (e.g., in response to) a random variable X for the failure data follows a binomial distribution to which a standard failure rate is applied, a significance probability (p-value) that an event more extreme than a failure rate detected at the detection time point will occur may be calculated to determine how rare the failure rate at the detection time point, as compared with the standard failure rate.

As described above, the significance probability (p-value) that an event more extreme than a failure rate detected at the detection time point will occur may be calculated based on a result obtained by approximating the failure data to a normal distribution to index how abnormally the failure rate at the detection time point has been increased, as compared the past. Thus, detection may be made as to whether the failure data is abnormal. In some example embodiments, a command signal may be generated and/or transmitted in response to a determination that the failure data is abnormal, where the command signal may cause one or more devices to implement failure rate management, such as performing selective adjustments to one or more portions (e.g., parameters, aspects, etc.) of a manufacturing process associated with the failure data (e.g., adjusting actuators, fluid supply valves, programmed control of manufacturing devices, etc.) to preemptively reduce failures of tests by devices under test which are products of and/or representative of the manufacturing process. However, when (e.g., in response to) the failure rate is significantly as low as a level of several PPM, a method of detecting abnormalities by approximating the failure data to a normal distribution may cause the above-described underestimation issue.

Accordingly, the method of detecting abnormalities according to some example embodiments may use an exact test based on a binomial distribution to reduce or prevent an underestimation issue and to improve detection accuracy, thereby enabling preemptive management of the failure rate (e.g., adjusting a manufacturing process to reduce the occurrence of defects in products of the manufacturing process). In operation S240, a detection failure rate at the detection time point may be calculated based on the calculated significance probability (p-value).

As an example, the detection failure rate used in the method of detecting abnormalities according to some example embodiments may refer to a significant degree of the failure rate at the detection time point. Operation S240 of the flowchart illustrated in FIG. 3 may correspond to operation S110 of the flowchart illustrated in FIG. 2.

When (e.g., in response to) the failure data X follows a binomial distribution in which a population ratio is p, a detection failure rate APₖ may be calculated by the following Equation 1.

APₖ=1−pᵥₐₗᵤₑ [Equation 1]

where pᵥₐₗᵤₑ may be a significant probability that a failure rate higher than a reference failure rate will be detected, and may refer to how scarcely the failure rate at a detection time point is an event occurs, as compared with the reference failure rate calculated by failure data at a plurality of points in time in the past. As an example, the pᵥₐₗᵤₑ may be calculated in the form of a conditional probability as in the following Equation 2.

pᵥₐₗᵤₑ=P(X≥x|p=p_{ref}) [Equation 2]

where p_{ref} may be a reference failure rate calculated based on the failure rate at a plurality of points in time included in a particular (or, alternatively, predetermined) period before the detection time point. As an example, p_{ref} may be calculated by the following Equation 3.

$$Pref = \frac{{\sum }_{i = k - j - 1}^{k} {x}_{i}}{{\sum }_{i = k - j - 1}^{k} {n}_{i}} \qquad [ Equation 3 ]$$

where j may be a length of the particular (or, alternatively, predetermined) period and k may be a length from a starting point of the particular (or, alternatively, predetermined) period to the detection time point, xₖ may be the number of abnormal samples at the detection time point, and nₖ may be the number of populations at the detection time point, for example, the number of samples.

In the method of detecting abnormalities according to some example embodiments, the calculated detection failure rate may be used to calculate an abnormality index. The calculated abnormality index may be compared with a size of an index corresponding to a control limit, and detection may be made as to whether the failure data is abnormal at the detection time point, based on a result of the comparison.

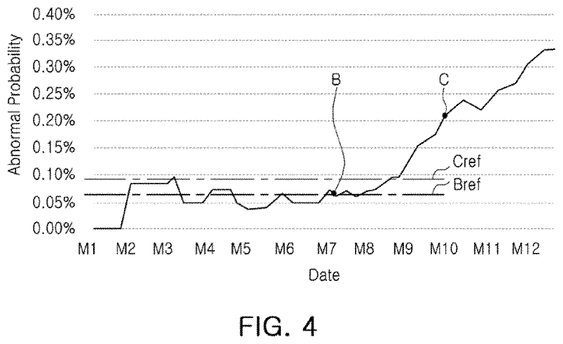

FIGS. 4, 5, and 6 are diagrams illustrating an effect of a method of detecting abnormalities according to some example embodiments.

FIG. 4 may illustrate an example of a detection failure rate calculated depending on operations of the flowchart illustrated in FIG. 3 at a plurality of points in time. In a detection failure rate graph of FIG. 4, a first point “B” in which the failure rate is in a normal state and a second point “C” in which the failure rate is in an abnormal state may be illustrated.

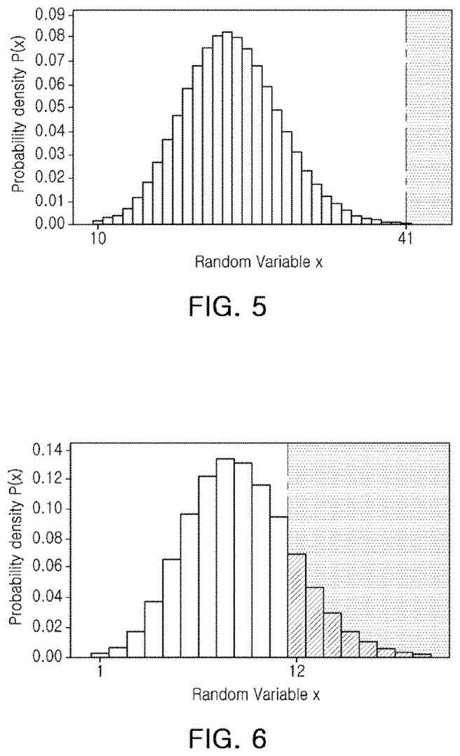

FIGS. 5 and 6 are diagrams illustrating a significance probability calculated at a time point corresponding to the second point “C” in which the failure rate is in an abnormal state and a significance probability at a time point corresponding to the first point “B” in which when (e.g., in response to) the failure rate is in a normal state, respectively.

Referring to FIG. 4, pieces of failure data at a plurality of points in time, included in a particular (or, alternatively, predetermined) period before the time point corresponding to the first point “B,” may be collected to calculate a detection failure rate at the first point “B.” Similarly, pieces of failure data at a plurality of points in time, included in a particular (or, alternatively, predetermined) period before the time point corresponding to the second point “C,” may be collected to calculate the detection failure rate at the second point “C.” For example, the pieces of failure data collected to calculate the detection failure rate at the first point “B” and the second point “C” may be different from each other.

In the method of detecting abnormalities according to some example embodiments, reference failure rates Cref and Bref for calculating the detection failure rates at the first point “B” and the second point “C” may be calculated using Equation 3. As an example, the first reference failure rate Bref for calculating the detection failure rate at the first point “B” may be different from the second reference failure rate Cref for calculating the detection failure rate at the second point “C.”

In FIG. 4, since the first point “B” corresponds to the time point at which the failure rate is in a normal state and the second point “C” corresponds to the time point at which the failure rate is in an abnormal state, the first reference failure rate Bref may be lower than the second reference rate Cref. However, this is only an example and example embodiments may not be limited thereto.

In the method of detecting abnormalities according to some example embodiments, the detection failure rates at the first point “B” and the second point “C” may be calculated using Equations 1 and 2. As an example, the detection failure rate at the first point “B” may be about 0.075%, and the detection failure rate at the second point “C” may be about 0.22%. However, this is only an example and example embodiments are not limited thereto.

Referring to FIGS. 5 and 6, a significance probability may be calculated from failure data collected at the points in time corresponding to the first point “B” and the second point “C.” As an example, FIG. 5 may represent a significance probability calculated from failure data collected at the time point corresponding to the second point “C” in which the failure rate is in an abnormal state. On the other hand, FIG. 6 may represent a significance probability calculated from failure data collected at the time point corresponding to the first point “B” in which the failure rate is in a normal state. The significance probability when (e.g., in response to) the failure rate is in the normal state may be lower than the significance probability when (e.g., in response to) the failure rate is in the abnormal state.

As described in the example of FIGS. 5 and 6, in the method of detecting abnormalities according to some example embodiments, detection may be made as to whether a failure rate is abnormal, using an exact test, to address an issue of underestimation of the failure rate. Moreover, in the method of detecting abnormalities according to some example embodiments, a significant probability of the failure rate may be converted into a value between 0 and 1, rather than an absolute numerical value of the failure rate, to compare failure rate levels of products having different sizes of control limits and average failure rates.

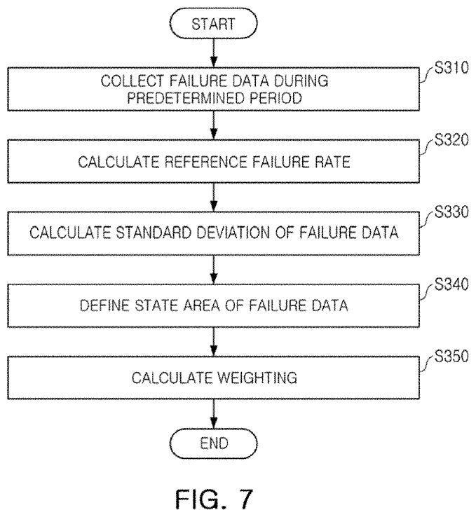

FIG. 7 is a flowchart illustrating a method of detecting abnormalities according to some example embodiments.

The flowchart illustrated in FIG. 7 may be a diagram illustrating a process of calculating weighting included in the method of detecting abnormalities according to the flowchart illustrated in FIG. 2.

Referring to FIG. 7, a method of detecting abnormalities according to some example embodiments may start with operation S310 in which failure data is collected at a plurality of points in time included in a particular (or, alternatively, predetermined) period. In operation S320, a reference failure rate, used to detect whether the failure data is abnormal at a detection time point, may be calculated using the collected failure data. Operations S310 and S320 may correspond to operations S210 and S220 of the flowchart illustrated in FIG. 3. As an example, a statistical hypothesis test may be used to detect whether failure data is abnormal at the detection time point.

A general method of detecting abnormalities and a general method of managing a failure rate may detect an abnormally changing trend of a failure rate, but suffer from difficulty in determining a management direction in consideration of the target failure rate. As an example, in a case in which there is an increase in the failure rate in a stable area in which the failure rate may be stably controlled and a case in which there is an increase in the failure rate in an alert area adjacent to the target failure rate may be managed to be different from each other even when the cases have the same degree of an increase in failure rate. However, a method of detecting abnormalities according to the related art may not take into account a target failure rate even when the target failure rate is set, so that noise such as detection of abnormalities in failure data may occur even when a failure rate is changed within a stable range.

In the method of detecting abnormalities according to some example embodiments, areas corresponding to states of failure data may be subdivided based on the target failure data and managed to reduce or prevent unnecessary noise from occurring.

The method of detecting abnormalities according to some example embodiments may include operation S330 in which a standard deviation of failure data at a plurality of points in time included in a particular (or, alternatively, predetermined) period using a calculated reference failure rate to define a plurality of state areas. The standard deviation of the failure data may be calculated by the following Equation 4.

σ=\sqrt{p_{ref}(1−p_{ref})/n} [Equation 4]

where p_{ref} may be a reference failure rate and n may be average shipment quantity of products.

In operation S340, a size of the failure data may be defined as a plurality of state areas based on the calculated standard deviation. In operation S350, the failure data at a detection time point may be determined to be in a state corresponding to one of the plurality of defined state areas. As an example, a failure rate of a product may be managed based on the state of the failure data at the detection time point.

In S350, in the method of detecting abnormalities according to some example embodiments, weighting may be calculated based on a difference between the failure data at the detection time point and the target failure data. The weighting may determine how sensitively an increase in abnormality occurs with respect to an increase in size of the failure data. For example, in the method of detecting abnormalities according to some example embodiments, sensitivity to a rising trend of failure data may be adjusted using the weighting when (e.g., in response to) the size of the failure data is smaller than that of the target failure data.

As an example, the smaller a difference between the size of the failure data at the detection time point and the size of the target failure data, the larger the weighting. Accordingly, when (e.g., in response to) the failure data is proximate to the target failure data, an increase in the failure data may be sensitively accepted. Meanwhile, as the failure data is further away from the target failure data, an increase in the failure data may be insensitively accepted.

In the method of detecting abnormalities according to some example embodiments, the weighting may be calculated by the following Equation 5, and weighting W(zₖ) depending on Equation 5 may be calculated by substituting the difference between the size of the failure data and the size of the target failure data into an activation function. As an example, the activation function used in the method of detecting abnormalities according to some example embodiments may be a Leaky-ReLU function. However, this is only an example and example embodiments may not be limited thereto.

$$W ( {z}_{k} ) = \{ \begin{matrix}max ( a ( {z}_{k} + 1 ) ) + 1 , {z}_{k} < - 1 \\ b ( {z}_{k} + 1 ) + 1 , {z}_{k} \geq - 1\end{matrix} \qquad [ Equation 5 ]$$

where “a” may be a first slope, a particular (or, alternatively, predetermined) constant, “b” may be a second slope, a particular (or, alternatively, predetermined) constant, and zₖ may be calculated by the following Equation 6.

$${z}_{k} = \frac{\frac{{x}_{k}}{{n}_{k}} - Target}{σ} \qquad [ Equation 6 ]$$

where xₖ may be the number of abnormal samples at the detection time point, and nₖ may be the number of populations at the detection time point, for example, the number of samples, Target may be target failure data, and σ may be a standard deviation of the failure data at a plurality of points in time included in the particular (or, alternatively, predetermined) period calculated by Equation 4.

The weighting may be calculated by applying different first and second slopes based on a particular point. As an example, the particular point may correspond to a point at which the failure data is the same as a difference between the target failure data and the standard deviation, and the first and second slopes may be determined by an additional optimization operation.

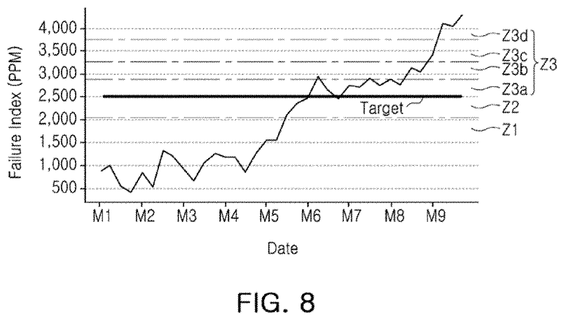

FIG. 8 is a diagram illustrating a plurality of state areas defined in a method of detecting abnormalities according to some example embodiments.

Referring to FIG. 8, in the method of detecting abnormalities according to some example embodiments, failure data may be defined as being in a state corresponding to one of a plurality of state areas. As an example, the plurality of state areas may include a first area Z1, a second area Z2, and a third area Z3.

In the method of detecting abnormalities according to some example embodiments, a state of the failure data at a detection time point may be determined to correspond to one of the plurality of state areas. As an example, the state of the failure data at the detection time point may be determined based on a difference between the failure data at the detection time point and target failure data Target.

In the method of detecting abnormalities according to some example embodiments, the first area Z1 may be a stable area indicating that failure data obtained at the detection time point is normal and is normally managed. The second area Z2 may be a monitoring area indicating that the failure data obtained at the detection time point is normal, but needs to be continuously observed and managed. The third area Z3 may be a risk area indicating that the failure data obtained at the detection time point is outside of a normal range.

Accordingly, when (e.g., in response to) the failure data at the detection time point is disposed in the first area Z1 or the second area Z2, a size of the failure data at the detection time point may be smaller than that of the target failure data Target. On the other hand, when (e.g., in response to) the failure data at the detection time point is disposed in the third area Z3, the size of the failure data at the detection time point may be larger than that of the target failure data Target.

The first area Z1 and the second area Z2 may have boundaries adjacent to each other. Similarly, the second area Z2 and the third area Z3 may have boundaries adjacent to each other. For example, the boundary between the second area Z2 and the third area Z3 adjacent to each other may correspond to the size of the target failure data Target.

In the method of detecting abnormalities according to some example embodiments, the third area Z3 may include a plurality of risk regions Z3a, Z3b, Z3c, and Z3d defined based on the extent to which the size of the failure data at the detection time point is greater than that of the target failure data Target.

In FIG. 8, the plurality of risk areas Z3a, Z3b, Z3c, and Z3d is illustrated as being four areas, but this is only an example and example embodiments may not be limited thereto. As an example, the third area Z3 may be divided into four or less areas or may be divided into four or more areas. Accordingly, the failure data may be managed after being subdivided into a plurality of state areas.

As described above, the plurality of state areas may be defined using the standard deviation of the failure data at a plurality of points in time included in a particular (or, alternatively, predetermined) period based on the target failure data Target. As an example, a boundary between the second area Z2 and the third area Z3 may correspond to the size of the target failure data Target, and a boundary between the first area Z1 and the second area Z2 may correspond to a difference between the size of the target failure data Target and the standard deviation of the failure data.

The first area Z1, the second area Z2, and each of the plurality of risk areas Z3a, Z3b, Z3c, and Z3d may be separated by a standard deviation interval based on the size of the target failure data Target. However, this is only an example and example embodiments may not be limited thereto. As an example, an interval between the plurality of areas may be set to be different, as necessary.

Referring to FIGS. 7 and 8 together, in the method of detecting abnormalities according to some example embodiments, weighting and a plurality of state areas may be defined based on the difference between the failure data at the detection time point and the target failure data Target. Accordingly, when (e.g., in response to) there is a rising trend of failure data, detection may be accurately and precisely made as to whether the rising trend of failure data is abnormal.

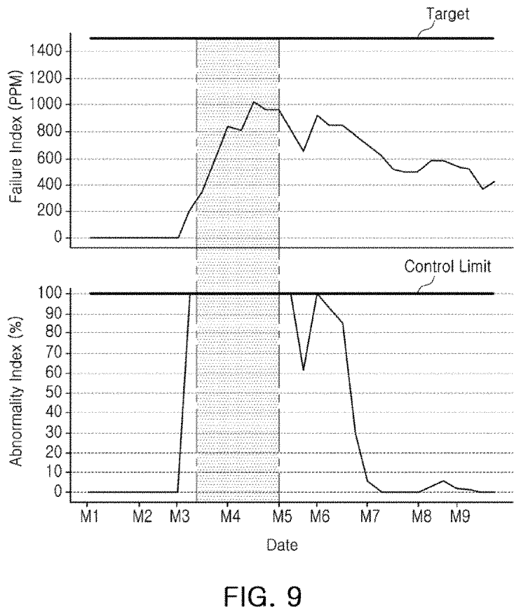

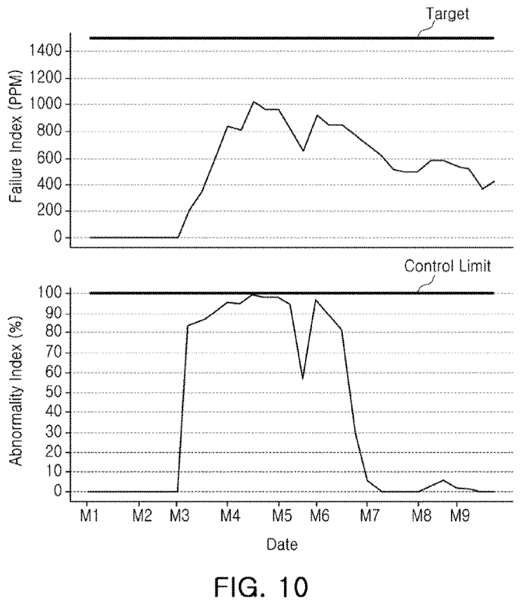

FIGS. 9 and 10 are diagrams illustrating an effect of a method of detecting abnormalities according to some example embodiments.

FIG. 9 may be a diagram illustrating a result of processing failure data when (e.g., in response to) no weighting is applied to the failure data collected at a detection time point. Meanwhile, FIG. 10 may be a diagram illustrating a result of processing failure data when (e.g., in response to) the weights described in FIGS. 7 and 8 are applied to the failure data collected at a detection time point.

Referring to the flowchart illustrated in FIG. 2, the method of detecting abnormalities according to some example embodiments may include operation S130 in which an abnormality index is obtained by multiplying the calculated detection failure rate by weighting. As an example, the abnormality index may be an index indicating how abnormally the failure data at a detection time point is actually increased.

Referring to FIGS. 7 and 8, weighting may be calculated based on a difference between the failure data and the target failure data Target. As an example, the weighting may be calculated by the above-described Equation 5. A particular point, serving as a criterion for determining the first slope and the second slope applied to the weighting calculation may correspond to a boundary between the first area Z1 and the second area Z2.

For example, weighting based on the failure data having a state corresponding to the first area Z1 may be calculated by an activation function to which the first slope is applied. On the other hand, weighting based on the failure data having a state corresponding to the second area Z2 may be calculated by an activation function to which the second slope is applied.

Referring to FIGS. 9 and 10, failure data may refer to the number of abnormal samples per million samples. In the method of detecting abnormalities according to some example embodiments, the failure data at the detection time point may be compared with the target failure data Target to determine a state of the failure data at the detection time point may be determined. In addition, the abnormality index may be compared with the control limit to determine whether a change in failure rate at the detection time point is abnormal.

Referring to FIG. 9, when (e.g., in response to) no weighting is applied to the calculation of the abnormality index, a rising trend of the failure data may be reflected in the abnormality index, irrespective of a difference between a size of the failure data at the detection time point and the target failure data Target. As an example, in the process of reflecting the rising trend of the failure data in the abnormality index, a case in which the failure data is disposed in a stable area, among a plurality of state areas, may not be distinguished from a case in which the failure data is disposed in a monitoring area, among the plurality of state areas.

As an example, rising of the failure data collected at a plurality of points in time included in a period between M3 to M4 may be detected as abnormal rising in spite of a significant difference from the target failure data Target. Accordingly, in the period between M3 and M5, a size of actual failure data may be smaller than the size of the target failure data Target. In addition, even when (e.g., in response to) the failure rate is within a controllable range and thus may be stabilized, the calculated abnormality index may appear to exceed the control limit.

Referring to FIG. 10, when (e.g., in response to) weighting is applied to the calculation of the abnormality index, the extent to which the rising trend of the failure data is reflected in the abnormality index may vary depending on the difference between the size of the failure data at the detection time point and the target failure data Target. As an example, even when (e.g., in response to) the failure data rises by the same level, rising of the failure data may be reflected more sensitively in the case in which the failure data is disposed in the monitoring area, among the plurality of state areas, than in the case in which the failure data is disposed in the stable area, among the plurality of state areas.

As an example, the size of the failure data collected at the plurality of points in time included in the section between M3 and M4 has been increased, but there is still a significant difference from the target failure data Target. Therefore, rising of the failure data may not be reflected in the abnormality index as abnormal rising. Accordingly, the abnormality index calculated in the period between M3 and M5 may not appear to exceed the control limit.

In other words, in the method of detecting abnormalities according to some example embodiments, an abnormality index may be calculated using weighting and detection may be made as to whether a failure rate is abnormal using the abnormality index, thereby addressing a noise issue which may occur when (e.g., in response to) no weighting is used. In addition, the plurality of state areas may be defined to calculate weighting based on a subdivided criterion and to manage the failure data.

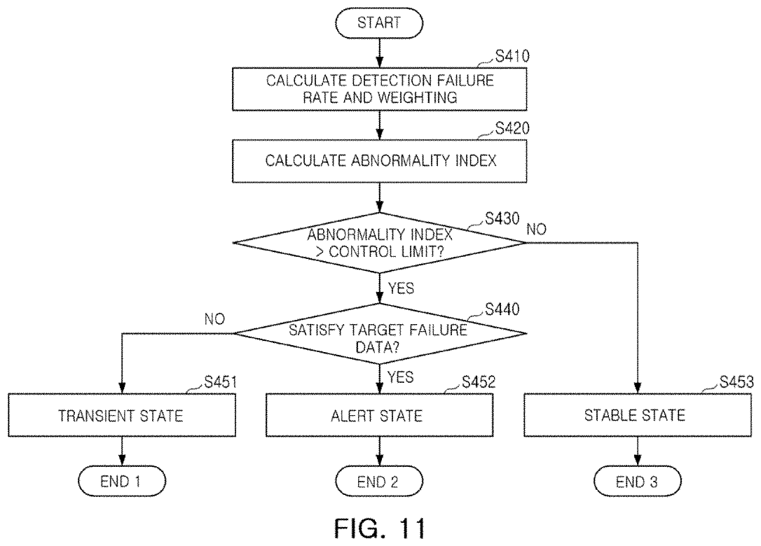

FIG. 11 is a flowchart illustrating a method of detecting abnormalities according to some example embodiments.

The flowchart illustrated in FIG. 11 may be a diagram illustrating a process of performing detection of abnormalities included in the method of detecting abnormalities according to the flowchart illustrated in FIG. 2.

Referring to FIG. 11, the method of detecting abnormalities according to some example embodiments may include operation S410 in which a detection failure rate and weighting are calculated from failure data at a plurality of points in time included in a particular (or, alternatively, predetermined) period.

As an example, the detection failure rate may be calculated based on a reference failure rate calculated from the failure data and failure data at a detection time point. The weighting may be calculated based on a difference between the failure data at the detection time point and the target failure data. Operation S410 may correspond to operations of the method of detecting abnormalities according to some example embodiments described with reference to FIGS. 3 and 7. However, this is only an example and example embodiments may not be limited thereto.

The method of detecting abnormalities according to some example embodiments may include operation S420 in which an abnormality index is calculated by multiplying the calculated detection failure rate by the weighting. Using the calculated abnormality index, a determination may be made as to whether change in the failure data at the detection time point exceeds an actual controllable range and detection may be made as to whether the failure data at the detection time point is abnormal.

For example, in operation S430, the abnormality index and an index corresponding to the control limit may be compared with each other according to the method of detecting abnormalities. As an example, in operation S453, when (e.g., in response to) the value of the abnormality index is smaller than the size of the index corresponding to the control limit, the failure rate at the detection time point may be determined to be in a stable state. For example, where the method of detecting abnormalities relates to a manufacturing process for manufacturing semiconductor products, and where the failure data and thus failure rate relate to failures of semiconductor products of the manufacturing process in relation to one or more tests thereof, the determination at S453 may include generating and/or transmitting a command signal to cause a device to maintain process variables (e.g., parameters and/or aspects) of the manufacturing process at present values, thereby selectively refraining from adjusting the process and thus to maintain performance, reliability, cost-effectiveness, efficiency, or the like of the manufacturing process and/or products thereof.

Meanwhile, in operation S440, when (e.g., in response to) the value of the abnormality index is greater than the size of the index corresponding to the control limit, the size of the failure data at the detection time point and the size of the target failure data may be compared with each other. As an example, in operation S452, when (e.g., in response to) the value of the abnormality index is greater than the size of the factor corresponding to the control limit but the size of the failure data satisfies the target failure data, for example, when (e.g., in response to) the size of the failure data is lower than the target failure data, a failure rate at the detection time point may be determined to be in an alert state.

On the other hand, in operation S451, when (e.g., in response to) the value of the abnormality index is greater than the size of the index corresponding to the control limit and the size of the failure data is larger than the size of the target failure data, the failure rate at the detection time point may be determined to be in a transient state.

In the method of detecting abnormalities according to some example embodiments, the alert state may refer to a state in which there is no problem in failure rate at the detection time point but, as non-ideal rising out of control is detected, failure data outside of target failure data may be detected sooner or later. Accordingly, when (e.g., in response to) the alert state is detected, a manager may actively manage a failure rate. For example, where the method of detecting abnormalities relates to a manufacturing process for manufacturing semiconductor products, and where the failure data and thus failure rate relate to failures of semiconductor products of the manufacturing process in relation to one or more tests thereof, actively managing the failure rate at S452 may include generating and/or transmitting a command signal to cause a device to perform selective adjustment of one or more process variables of the manufacturing process from present values, thereby selectively adjusting the manufacturing process to reduce defects in the manufactured semiconductor products and thus to reduce the failure rate and thus to improve performance, reliability, cost-effectiveness, efficiency, or the like of the manufacturing process and/or products thereof.

On the other hand, the transient state may refer to a state in which a problem has already occurred in the failure rate at the detection time point. Accordingly, when (e.g., in response to) the transient state is detected, the manager may improve internal quality to improve the failure rate. For example, where the method of detecting abnormalities relates to a manufacturing process for manufacturing semiconductor products, and where the failure data and thus failure rate relate to failures of semiconductor products of the manufacturing process in relation to one or more tests thereof, improving internal quality at S451 may include generating and/or transmitting a command signal to cause a device to perform selective adjustment of one or more process variables of the manufacturing process from present values, thereby selectively adjusting the manufacturing process to reduce defects in the manufactured semiconductor products and thus to reduce the failure rate and thus to improve performance, reliability, cost-effectiveness, efficiency, or the like of the manufacturing process and/or products thereof.

In the method of detecting abnormalities according to some example embodiments, before a failure rate in a transient state is detected, a failure rate in an alert state may be preemptively detected to respond thereto. Accordingly, a failure rate may be effectively managed such that the failure rate may be maintained in a stable state without reaching the transient state.

For example, in the method of detecting abnormalities according to some example embodiments, abnormal rising of failure data collected at particular (or, alternatively, predetermined) time intervals may be detected in advance, so that that a risk that a detection failure rate at the detection time point exceeds the target failure rate may be quantified to be managed.

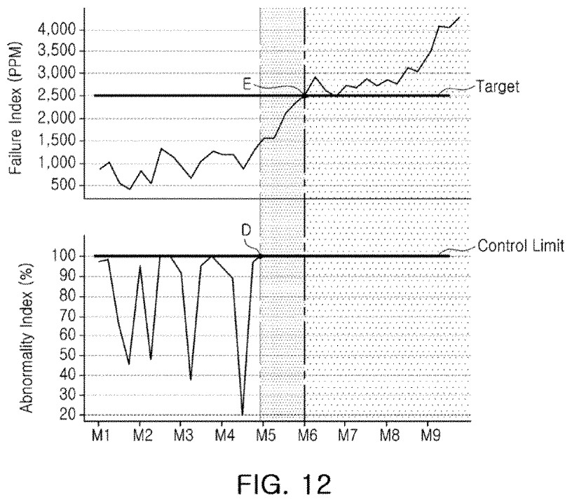

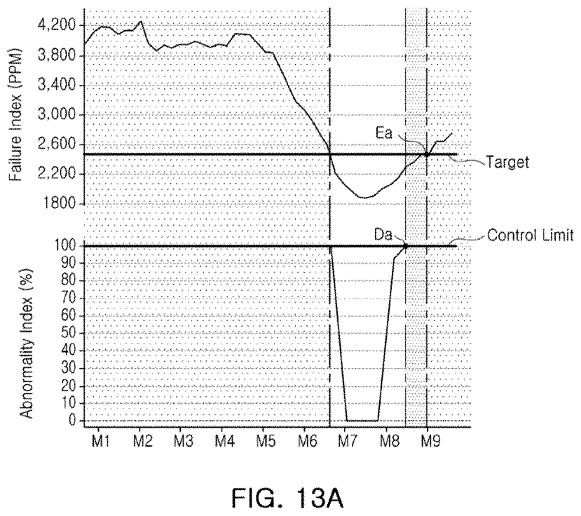

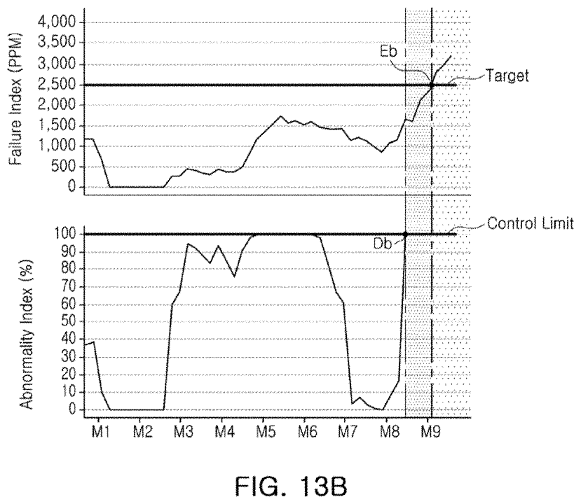

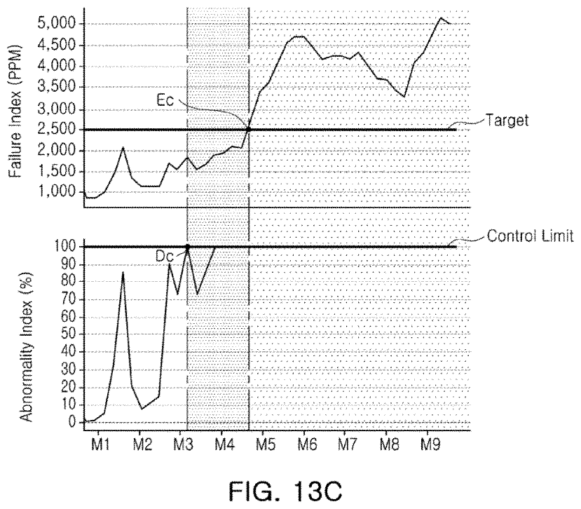

FIG. 12 is a diagram illustrating an application example of a method of detecting abnormalities some example embodiments. FIGS. 13A, 13B, and 13C are diagrams illustrating an application example of a method of detecting abnormalities some example embodiments.

Referring to FIG. 12 and FIGS. 13A to 13C, all pieces of failure data at the current time point may exceed target failure data Target. However, the method of detecting abnormalities according to some example embodiments may be applied to preemptively detect that pieces of failure data after a specific time point exceed the target failure data Target, based on the failure data collected at a plurality of detection time points, and to appropriately respond to a result of the detection.

When (e.g., in response to) an abnormality index corresponding to the failure data at the detection time point is lower than an index corresponding to a control limit, the failure data at the detection time point may be determined to be in a stable state. As an example, referring to FIG. 12, the failure data collected at points in time M1 to M4, points in time before a first point D at which an abnormality index is the same as the index corresponding to the control limit, may be in a stable state.

Meanwhile, when (e.g., in response to) the abnormality index corresponding to the failure data at the detection time point is greater than the index corresponding to the control limit, a size of the failure data at the detection time point and a size of the target failure data Target may be compared with each other. In addition, when (e.g., in response to) the size of the failure data at the detection time point is smaller than the size of the target failure data Target, a state of the failure data at the detection time point may be determined as an alert state.

Referring to FIG. 12, pieces of data collected at M5 and M6, points in time between a first point “D” at which an abnormality index starts to be larger than an index corresponding to the control limit and a second point “E” at which the size of the failure data is the same as the size of the target failure data Target, may be in the alert state. For example, in the method of detecting abnormalities according to some example embodiments, the size of the failure data may be determined to be continuously increased even when (e.g., in response to) the size of the failure data is smaller than the size of the target failure.

In addition, when (e.g., in response to) the size of the failure data at the detection time point is larger than the size of the target failure data Target, the state of the failure data at the detection time point may be determined to be a transient state. Referring to FIG. 12, failure data collected at M7 to M9, points in time after the second point “E” at which the size of the failure data starts to be larger than the size of the target failure data, may be in a transient state.

As an example, when (e.g., in response to) the failure data at a first time point between M1 to M4 is in a stable state and the failure data at a second time point between M7 to M9 is in a transient state, the failure data at a third time point between the first time point and the second time point may be in an alert state. For example, an abnormality index calculated based on the failure data in the alert state may be obtained before the failure data in the transient state is obtained. Thus, the method of detecting abnormalities according to some example embodiments may be applied to preemptively manage the failure rate such that the failure rate does not reach the transient state.

FIGS. 13A to 13C may be diagrams illustrating a case in which a method of detecting abnormalities according to some example embodiments is applied to different products.

Referring to FIG. 13A, a failure rate of a corresponding product at points in time M1 to M6 may be in a transient state in which detected failure data exceeds target failure data, and may be gradually improved according to internal quality management. The failure rate of the corresponding product may be maintained in a stable state at points in time M7 to M8, an alert state may be detected at a first point Da, and a transient state may be detected at a second point Ea.

In the method of detecting abnormalities according to the present inventive concepts, a change in failure data for a product, on which internal quality management has been performed, may be preemptively detected to effectively perform continuous internal quality management.

Referring to FIG. 13B, a failure rate of a corresponding product at points in time M1 to M8 may be in a stable state in which a detected abnormality index does not exceed a control limit even after several fluctuations. In the failure rate of the corresponding product, an alert state may be detected at a first point Db and a transient state may be detected at a second point Eb.

In the method of detecting abnormalities according to the present inventive concepts, even when there is a fluctuation in failure rate of a product, abnormal rising of the failure data of the product may be accurately detected, without a noise issue, using weighting in consideration of the target failure data Target.

Referring to FIG. 13C, a failure rate of a corresponding product at points in time M1 to M3 may be in a stable state in which an abnormality index does not exceed a control limit. In the failure rate of the corresponding product, an alert state may be detected at a first point Dc and a transient state may be detected at a second point Ec.

Referring to FIGS. 13A to 13C, even in the case in which a method of detecting abnormalities according to some example embodiments is applied to different products, detection of abnormalities may be performed based on the same criterion when a control limit and target failure data are given. Accordingly, failure rates between the different products may be effectively compared with each other.

As described above, in a method of detecting abnormalities according to some example embodiments, abnormality of failure data may be detected based on a detection failure rate, calculated by an exact test, to reduce or prevent an underestimation issue from occurring in a field having a significantly low failure rate.

Detection of abnormalities may be performed using weighting, calculated based on a difference between failure data at a detection time point and target failure data, to reduce a possibility that noise occurs.

A plurality of state areas may be defined based on a difference between failure data at a detection time point and target failure data to effectively manage a failure rate.

Abnormality of a failure rate may be detected in advance in a field having a significantly low failure rate using an abnormality index, calculated using a detection failure rate and weighting, to effectively manage risks.

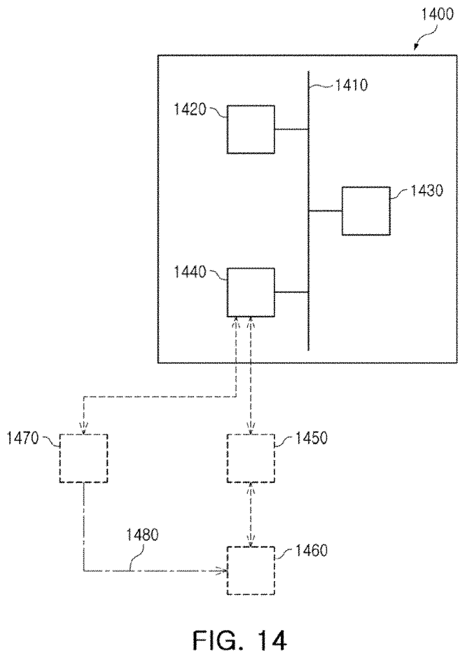

FIG. 14 is a block diagram of an electronic device according to some example embodiments. Said electronic device may include and/or implement any of the electronic devices, products, systems, boards, modules, units, controllers, and/or circuits included in any of the example embodiments, including any of the devices to and/or for which a method of detecting abnormalities may be applied. Said electronic device may be configured to perform any or all of the operations of any of the methods (e.g., methods of detecting abnormalities) according to any of the example embodiments, including without limitation any or all of the operations of any or all of the methods shown in FIGS. 2, 3, 7, and/or 11.

Referring to FIG. 14, an electronic device 1400 may include a processor 1420, a memory 1430, and an interface 1440 that are electrically coupled together via a bus 1410. The interface 1440 may be a communication interface (e.g., a wired or wireless communication transceiver).

As shown in FIG. 14, where the electronic device 1400 is configured to perform a method of detecting abnormalities according to any of the example embodiments, the interface 1440 may be communicatively coupled to an external device 1450 which may be a testing device configured to generate failure data based on tests being performed on one or more product devices 1460, such that the electronic device 1400 may receive failure data via the interface 1440 and process the failure data at the processor 1420 as part of performing any of the methods of detecting abnormalities. Additionally, the electronic device 1400 may generate command signals which may be transmitted to one or more external devices 1470 associated with a manufacturing process 1480 (e.g., a process to manufacture the one or more product devices 1460) based on performing a method of detecting abnormalities and determining an abnormal failure rate, abnormality index, etc. as part of performing the method (e.g., based on determining a transient state or alert state at S451 or S452 as described above with reference to FIG. 11, as part of managing the failure rate at S150 in response to a determination that the abnormality index is detected to be outside of a controllable range and/or that the failure data at the detection time point is abnormal as described above with reference to FIG. 2, etc.), thereby causing the one or more external devices 1470 to implement adjustments to the manufacturing process 1480 (e.g., one or more process variables thereof) to reduce failure rates of products (e.g., the one or more product devices 1460) of the manufacturing process 1480. Product devices 1460 may then be manufactured according to the adjusted manufacturing process 1480 to thereby manufacture products associated with a reduced failure rate and thus having improved reliability.

The one or more product devices 1460 may be products of a manufacturing process 1480 which may be controlled by external device 1470 (e.g., semiconductor products of a semiconductor product manufacturing process). The external device 1450 may generate failure data based on one or more tests being formed on one or more of the product devices 1460. The external device 1450 may perform the tests on the one or more product devices 1460, may generate failure data based on receiving test results from additional devices which perform testes on the one or more product devices 1460, any combination thereof, or the like. Such tests may include an observation of one or more product devices 1460 for visible defects, applying electrical signals to an interface (e.g., electrodes, communication interface, etc.) of the one or more product devices 1460 and processing a response signal received from an interface (same or different) of the one or more product devices 1460 in response to the applied electrical signals to determine whether the one or more product devices 1460 passes or fails the test, or the like. Each of the external device 1450 and the one or more product devices 1460 and the one or more external devices 1470 may have the same structure and internal elements as the electronic device 1400 (e.g., including a processor 1420, memory 1430, interface 1440, bus, 1410, etc.).

The memory 1430, which may be a non-transitory computer readable medium, may store a program of instructions and/or other information. The memory 1430 may be a nonvolatile memory, such as a flash memory, a phase-change random access memory (PRAM), a magneto-resistive RAM (MRAM), a resistive RAM (ReRAM), or a ferro-electric RAM (FRAM), or a volatile memory, such as a static RAM (SRAM), a dynamic RAM (DRAM), or a synchronous DRAM (SDRAM). The processor 1420 may execute the stored program of instructions to perform one or more functions. For example, where the electronic device 1400 is included in and/or implements one or more methods of detecting abnormalities, the processor 1420 may be configured to process failure data received from the external devices 1450 via interface 1440 and, based on a result of the one or more methods (e.g., determining for example an alert state, transient state, or stable state as described with reference to FIG. 11), to selectively transmit commands to the external device 1470 via interface 1440 to cause the external device 1470 to selectively maintain or adjust one or more parameters or aspects (“portions”) of a manufacturing process 1480 for producing the one or more product devices 1460 (e.g., semiconductor products). In another example, the processor 1420 may execute programs of instruction stored at the memory 1430 to implement the functionality of any part of any method of detecting abnormalities as described herein, including any functionality of preemptively managing the failure rate, for example based on adjusting parameters or aspects of a manufacturing process 1480 (e.g., implementing the functionality of the external devices 1470, such that the external device 1470 may be omitted).

The processor 1420 may include processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processor 1420 may be configured to generate an output (e.g., a command signal, for example a signal that is transmitted to external device 1470 via interface 1440 to cause adjustment of a manufacturing process 1480 to reduce failure rates) based on such processing.

One or more of the processor 1420, memory 1430, and/or interface 1440 may be included in, include, and/or implement one or more instances of processing circuitry such as hardware including logic circuits, a hardware/software combination such as a processor executing software; or a combination thereof. In some example embodiments, said one or more instances of processing circuitry may include, but are not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. In some example embodiments, any of the memories, image sensors, memory units, or the like as described herein may include a non-transitory computer readable storage device, for example a solid state drive (SSD), storing a program of instructions, and the one or more instances of processing circuitry may be configured to execute the program of instructions to implement the functionality of some or all of any of the processor 1420, memory 1430, interface 1440, or the like according to any of the example embodiments as described herein, including performing any of the methods as described herein, including any of the methods of detecting abnormalities according to any of the example embodiments.

In some example embodiments, some or all of the systems, units, modules, devices, circuits, controllers, and/or elements thereof as described herein with reference to any of the drawings may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), an application processor (AP), a microcomputer, a field programmable gate array (FPGA), and programmable logic unit, a microprocessor, application-specific integrated circuit (ASIC), a neural network processing unit (NPU), an Electronic Control Unit (ECU), and the like. In some example embodiments, the processing circuitry may include a non-transitory computer readable storage device, for example a solid state drive (SSD), storing a program of instructions, and a processor (e.g., CPU) configured to execute the program of instructions to implement the functionality of any of the elements of the systems, devices, and/or elements thereof as described herein, including without limitation the functionality of any portion of the testing systems, testing apparatuses, interface boards, devices under test, image sensors, electronic devices, or the like according to any of the example embodiments. It will be further understood that the processing circuitry may be configured to perform any of the methods as described herein, for example based on including include a non-transitory computer readable storage device, for example a solid state drive (SSD), storing a program of instructions, and a processor (e.g., CPU) configured to execute the program of instructions to implement (“perform”) any or all of the operations of any of the methods (e.g., methods of detecting abnormalities) according to any of the example embodiments, including without limitation any or all of the operations of any or all of the methods shown in FIGS. 2, 3, 7, and/or 11.

While example embodiments have been shown and described above, it will be apparent to those skilled in the art that modifications and variations could be made without departing from the scope of the present inventive concept as defined by the appended claims.

1. A method of detecting abnormalities, the method comprising:
calculating a reference failure rate using failure data at a plurality of points in time included in a particular period;
calculating a detection failure rate and a weighting, corresponding to failure data at a detection time point after the particular period, using the reference failure rate;
calculating an abnormality index based on multiplying the detection failure rate by the weighting;
comparing the abnormality index with an index corresponding to a control limit that is associated with stably controlling a failure rate; and
detecting whether the failure data at the detection time point is abnormal, based on a result of the comparison of the abnormality index with the index corresponding to the control limit.

2. The method of claim 1, further comprising:
comparing a size of the failure data at the detection time point with a size of a particular target failure data.

3. The method of claim 2, further comprising:
determining a state of the failure data at the detection time point as a state corresponding to one of a plurality of state areas based on a difference in a size of the failure data at the detection time point and a size of the particular target failure data.

4. The method of claim 2, wherein:
the weighting is increased as a difference in the size of the failure data at the detection time point and the size of the particular target failure data is decreased.

5. The method of claim 1, further comprising:
determining a state of the failure data at the detection time point as a stable state in response to a determination that the abnormality index corresponding to the failure data at the detection time point is lower than the index corresponding to the control limit.

6. The method of claim 5, further comprising:
comparing a size of the failure data at the detection time point and a size of a target failure data with each other in response to a determination that the abnormality index corresponding to the failure data at the detection time point is greater than the index corresponding to the control limit.

7. The method of claim 6, wherein:
a state of the failure data at the detection time point is determined as an alert state in response to a determination that the size of the failure data at the detection time point is smaller than the size of the target failure data.

8. (canceled)

9. (canceled)

10. The method of claim 1, wherein:
the abnormality index, calculated based on failure data in an alert state, is obtained before failure data in a transient state is obtained.

11. The method of claim 1, further comprising:
adjusting parameters of a manufacturing process in response to a detection that the failure data at the detection time point is abnormal; and
manufacturing products based on the adjusted parameters of the manufacturing process.

12. A method of detecting abnormalities, the method comprising:
calculating a reference failure rate using failure data at a plurality of points in time included in a particular period;
calculating a detection failure rate according to an exact test using the reference failure rate and failure data at a detection time point after the particular period;
calculating an abnormality index using the detection failure rate; and
detecting whether the failure data at the detection time point is abnormal, based on the abnormality index.

13. The method of claim 12, further comprising:
in response to a random variable X follows a binomial distribution in which a population ratio is p, calculating a detection failure rate APₖ by Equation 1,
$${AP}_{k} = 1 - P ( X \geq x \vert p = \frac{{\sum }_{i = k - j - 1}^{k} {x}_{i}}{{\sum }_{i = k - j - 1}^{k} {n}_{i}} ) \qquad [ Equation 1 ]$$
wherein, in Equation 1,
j is a length of the particular period,
k is a length from a starting point of the particular period to the detection time point,
xᵢ is a quantity of abnormal samples at the detection time point, and
nᵢ is a quantity of samples at each time point.

14. The method of claim 12, further comprising:
adjusting parameters of a manufacturing process in response to a detection that the failure data at the detection time point is abnormal; and
manufacturing products based on the adjusted parameters of the manufacturing process.

15. A method of detecting abnormalities, the method comprising:
calculating a reference failure rate using failure data at a plurality of points in time included in a particular period;
calculating a standard deviation of the failure data at the plurality of points in time, included in the particular period, using the reference failure rate;
defining a plurality of state areas including a first area, a second area, and a third area separated based on the standard deviation, a boundary between the second area and the third area corresponding to a size of target failure data;
determining an area, corresponding to a state of failure data at a detection time point after the particular period, among the plurality of state areas; and
calculating a weighting based on a difference between the failure data at the detection time point and the target failure data.

16. The method of claim 15, wherein:
the third area includes a plurality of risk areas defined depending on an extent to which a size of the failure data at the detection time point is larger than a size of the target failure data.

17. The method of claim 16, wherein:
the first area, the second area, and each of the plurality of risk areas are separated based on a size of the target failure data at an interval of the standard deviation.

18. The method of claim 15, wherein:
a size of failure data having a state corresponding to the first area is smaller than a size of the target failure data.

19. The method of claim 15, wherein:
a first slope, used to calculate the weighting based on the failure data at the detection time point having a state corresponding to the first area, is different from a second slope used to calculate the weighting based on the failure data at the detection time point having a state corresponding to the second area or the third area.

20. The method of claim 19, wherein:
the weighting is calculated as a weighting W(zₖ) by Equation 2, based on the failure data at the detection time point having the state corresponding to the first area,
W(zₖ)=max(a(zₖ+1))+1 [Equation 2]
wherein, in Equation 2,
“a” is the first slope and is a particular constant, and
zₖ is determined by Equation 3,
$${z}_{k} = \frac{\frac{{x}_{k}}{{n}_{k}} - Target}{σ} \qquad [ Equation 3 ]$$
wherein, in Equation 3,
xₖ is a quantity of abnormal samples at the detection time point,
nₖ is a quantity of samples at the detection time point,
Target is the target failure data, and
σ is a standard deviation of the failure data at the plurality of points in time included in the particular period.

21. The method of claim 19, wherein:
the failure data having the state corresponding to the second area and the third area is calculated as failure data W(zₖ) by Equation 4,
W(zₖ)=b(zₖ+1)+1 [Equation 4]
wherein, in Equation 4,
“b” is the second slope and is a particular constant, and
zₖ is determined by Equation 5,
$${z}_{k} = \frac{\frac{{x}_{k}}{{n}_{k}} - Target}{σ} \qquad [ Equation 5 ]$$
wherein, in Equation 5,
xₖ is a quantity of abnormal samples at the detection time point,
nₖ is a quantity of samples at the detection time point,
Target is the target failure data, and
σ is a standard deviation of the failure data at the plurality of points in time included in the particular period.

22. (canceled)

23. The method of claim 15, further comprising:
calculating an abnormality index according to the failure data at the detection time point and the weighting;
adjusting parameters of a manufacturing process in response to a result of comparison of the failure data at the detection time point is abnormal; and
manufacturing products based on the adjusted parameters of the manufacturing process.
